(19) United States
(12) Patent Application Publication
(10) Pub. No.: US 2012/0127578 A1
(43) Pub. Date: May 24, 2012

(54) ANTIREFLECTIVE TRANSPARENT EMI SHIELDING OPTICAL FILTER

(76) Inventors: Clark I. Bright, Tucson, AZ (US); Robert C. Fitzer, North Oaks, MN (US); John D. Le, Woodbury, MN (US)

(21) Appl. No.: 13/388,337

(22) PCT Filed: Jul. 26, 2010
(86) PCT No.: PCT/US10/43184

§ 371 Date: Feb. 1, 2012

Related U.S. Application Data
(60) Provisional application No. 61/230,845, filed on Aug. 3, 2009.

(51) Int. Cl. G02B 1/11; B05D 5/06; C23C 16/40; B05D 5/12

(52) U.S. Cl. 359/585; 427/109

(57) ABSTRACT

Antireflective transparent EMI shielding optical filters are provided that can be laminated to optical display devices using optically clear adhesives. The provided filters include electrically-conductive metal or metal alloy layers that can be continuous and patterned or unpatterned. Also included are methods of making the provided filters and touch sensors made using the provided filters.

### FIELD

Multi-component films useful as optically transparent display filters on electronic devices are provided.

### BACKGROUND

The use of electronic devices that include flat panel displays is very popular and is increasing at an accelerating rate. These electronic devices include, for example, flat panel displays that contain electroluminescent (EL) lamps, light-emitting diodes (LEDs), organic light-emitting diodes (OLEDs), or liquid crystal displays. Most of these displays require multiple filters to adjust performance characteristics of the display that include the degree of neutrality and level of transmitted color, the level of reflected radiation, and the transmission levels of undesirable near infrared and electromagnetic interference (EMI) radiation.

Optical filters with EMI shielding have been developed that can modify visible radiation, infrared radiation, adjust color, reduce reflection, and can shield the observer from harmful (EMI) radiation. Usually a number of different optical filters in combination with EMI shielding films, especially films with transparent conductive mesh configurations, have been used to produce the final, desired visual output of the device. Some of these optical filters have employed interference stacks (e.g., Fabry-Perot) of alternating conductors and dielectrics to adjust the optical performance characteristics of the filters, while also providing EMI shielding. The conductors in these stacks are usually metal layers and the dielectrics are usually metal oxides layers. The metal oxide layers can have a very slow deposition rate which can lead to high production costs. The use of multiple optical filters in electronic devices to obtain desired performance characteristics can increase costs, make the devices bulky, and cause considerable loss in transmission of the desired images. Additionally, the metal or metal oxide layers can lose desirable optical and/or electrical properties upon exposure to adverse environmental conditions.

### SUMMARY

There is a need for optical filters useful for electronic display devices that are lightweight, low-cost, and that can incorporate multiple desired features into one filter. Also there is a need for optical filters that can be easily tailored during production to adjust visible reflection, visible transmission, and to function as transparent electrical conductor. Such filters can provide EMI protection without adding more components or cost to the electronic display device. There is also a need for optical filters than can be easily applied to existing electronic display devices. Additionally, there is a need for optical filters that have improved corrosion resistance of the electrically-conductive layer. The electrically-conductive layers can be patterned and electrical connections can be made to conductive layers or patterns of the electrically-conductive layers. The use of the provided electrically-conductive optical filters with EMI shielding can have wide variety of uses, including electromagnetic shield, transparent electrical circuitry, transparent electrode for solar, display panel and touch panel, low emissivity window, security window, electrochromic window, defrost window, static dissipation, etc. The filter is desired to have high optical transmission and good electrical conductance. The filter is also desired to have low optical reflection to interfacial medium whether air gap or optical clear bonding film to enhance display contrast. The use of provided optical filters can offer a versatile approach to replacement of multiple optical film layers and EMI shielding to meet the requirements of certain optical displays such as, for example, display panels for use in handheld devices such as mobile phones.

An optically transparent display filter is provided that includes a transparent support that includes an optically clear adhesive and a multi-layer construction atop the support, the construction comprising a layer of a metal oxide upon the support, a polycrystalline seed layer comprising zinc oxide disposed upon the metal oxide layer, a conductive metal or metal alloy layer disposed upon the polycrystalline seed layer, and a transparent dielectric layer disposed upon the conductive metal or metal alloy layer, wherein the multi-layer construction is atop the support on the side opposite the optically clear adhesive. The electrically-conducting layer can be unpatterned or patterned. The provided filter can have antireflective layers and components built into it to increase transmission of visible light. The filter can also provide EMI shielding when included in or placed on a display panel, touch panel, or an electronic device.

In another aspect, a method of making a display filter is provided that includes providing a transparent support that includes an optically clear adhesive, coating a layer of metal oxide on top of the transparent support on the side opposite the adhesive, vapor coating a polycrystalline seed layer comprising zinc oxide or bismuth oxide directly upon the metal oxide layer, coating an electrically-conductive layer comprising a metal or metal alloy directly upon the polycrystalline seed layer, and depositing a transparent dielectric layer in contact with the electrically-conductive layer.

Also embodied is a touch sensitive electronic device that includes a transparent support that includes an optically clear adhesive, and a multi-layer construction atop the support, the construction comprising a layer of metal oxide upon the support, a polycrystalline seed layer comprising zinc oxide disposed upon the layer of metal oxide, a patterned conductive metal or metal alloy layer disposed upon the polycrystalline seed layer, a first barrier layer disposed upon the conductive metal or metal alloy layer, a second layer of metal oxide disposed on top of the first barrier layer, a second polycrystalline seed layer comprising zinc oxide disposed upon the second layer of metal oxide, a second patterned metal or metal alloy layer disposed upon the second polycrystalline seed layer, and a second barrier layer disposed upon the second conductive metal or metal alloy layer, wherein the multi-layer construction is atop the support on the side opposite the optically clear adhesive.

In yet another embodiment, a method of making a display filter is provided that includes providing an optically transparent display filter comprising a transparent support that includes an optically clear adhesive, a multi-layer construction atop the support on the side opposite the adhesive, the construction comprising a layer of metal oxide upon the support, a polycrystalline seed layer comprising zinc oxide disposed upon the metal oxide layer, a conductive metal or metal alloy layer disposed upon the polycrystalline seed layer, and a transparent dielectric layer disposed upon the conductive metal or metal alloy layer, and patterning the electrically-conducting metal or metal alloy layer.

In this document the articles “a”, “an”, and “the” are used interchangeably with “at least one” to mean one or more of the elements being described;

the term “adjacent” refers to layers in the provided filters that are in proximity to other layers. Adjacent layers can be contiguous or can be separated by up to three intervening layers;

the term “alloy” refers to a composition of two or more metals that have physical properties different than those of any of the metals by themselves;

the term “barrier layer” refers to a layer or a combination of layers that prevent or retard the diffusion of moisture or corrosive agents;

the term “contiguous” refers to touching or sharing at least one common boundary;

the term “dielectric” refers to material that is less conductive than metallic conductors such as silver, and can refer to transparent semiconducting materials, and insulators (including polymers);

the term “electromagnetic interference (EMI) shielding” refers to the reflection of electromagnetic waves by an electrically-conductive layer; and

the term “patterned” refers to a configuration or configurations that can include regular arrays or random arrays of features or structures or a combination of both.

The optically transparent display filters described herein can exhibit one or more advantages by providing lightweight, low-cost films that can be easily applied to an electronic display device and that can provide multiple features in one filter. These filter include an electrically-conducting layer that has improved corrosion resistance and can include low average reflection of less than 8% of actinic radiation between the wavelengths of 450 nm and 650 nm, high average transmission of above 80% of average actinic radiation between the wavelengths of 450 nm and 650 nm, and average effective EMI shielding with sheet resistance of less than 100 ohms/square. Typically, the transmission of these filters is measured at 550 nm wavelength. The provided filters can be useful on many electronic devices and can be particularly useful on liquid crystal display panels and touch screen panels such as those used on mobile hand-held phones.

The details of one or more embodiments are set forth in the accompanying drawings and description below. Other features, objects, and advantages will be apparent from the description and drawings, and from the claims.

### BRIEF DESCRIPTION OF THE DRAWINGS

FIGS. 1-6 are illustrations of different embodiments of the provided optically transparent display filters.

FIGS. 7A and 7B are illustrations of embodiments of provided optically transparent display filters mounted on liquid crystal display panels that have touch sensitivity.

FIG. 8 is an illustration of a liquid crystal display panel with EMI shielding and capacitive touch-sensitive layers that include embodiments of the provided filter.

FIG. 9 is a schematic of a process line that can be used to produce some embodiments of the provided optical filters.

FIGS. 10A and 10B graphically illustrate electrical (EMI shielding effectiveness) and optical (transmission) properties of an embodiment of the provided optical filters.

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art using the teachings disclosed herein. The use of numerical ranges by endpoints includes all numbers within that range (e.g. 1 to 5 includes 1, 1.5, 2, 2.75, 3, 3.80, 4, and 5) and any range within that range.

Optically transparent display filter are provided that include conductive metal or metal alloy thin films. The optically transparent display filters can be useful as components of active optical devices such as display panels including liquid crystal display panels. The multi-component films can include a transparent support that includes and optically clear adhesive. A variety of supports can be employed. The supports can be transparent, smooth or textured, uniform or non-uniform, and/or flexible or rigid. Typical supports that highly transparent, smooth, uniform, and flexible. Supports can also contain other coatings or compounds, for example, abrasion-resistant coatings (hardcoats) or absorbing dyes. Typical supports include flexible materials that can be roll-to-roll processed. Supports also can have a visible light transmission of at least about 80% at 550 nm. In some embodiments, supports can be flexible plastic materials can include thermoplastic films such as polyesters (e.g., PET), polyacrylates (e.g., poly(methyl methacrylate), PMMA), polycarbonates, polypropylenes, high or low density polyethylenes, polyethylene naphthalates, polysulfones, polyether sulfones, polyurethanes, polyamides, polyvinyl butyral (PVB), polyvinyl chloride, polyvinylidenedifluoride (PVDF), fluorinated ethylene propylene (FEP), and polyethylene sulfide; and thermoset films such as cellulose derivatives, polyimides, polyimide benzoxazoles, polybenzoxazoles, and high T_{g} cyclic olefin polymers. The supports can also include a transparent multilayer optical film (“MOF”) provided thereon with at least one crosslinked polymer layer, such as those described in U.S. Pat. No. 7,215,473 (Fleming). In many embodiments the supports include PET. Typically, the support has a thickness of about 0.01 mm to about 1 mm.

The supports include an optically clear adhesive (OCA). Optically clear pressure sensitive adhesives are well known to those of ordinary skill in the art. Pressure sensitive adhesives useful in the present invention include, for example, those based on natural rubbers, synthetic rubbers, styrene block copolymers, polyvinyl ethers, poly (meth)acrylates (including both acrylates and methacrylates), polyolefins, and silicones. Optically clear pressure sensitive adhesives are generally acrylate-based pressure sensitive adhesives. However, silicone based pressure sensitive adhesives, rubber resin based pressure sensitive adhesives, block copolymer-based adhesives, especially those comprising hydrogenated elastomers, or vinylether polymer based pressure sensitive adhesives may also have optically clear properties. Useful alkyl acrylates (i.e., acrylic acid alkyl ester monomers) include linear or branched monofunctional unsaturated acrylates or methacrylates of non-tertiary alkyl alcohols, the alkyl groups of which have from 4 to 14 and, in particular, from 4 to 12 carbon atoms. In some embodiments, the pressure sensitive adhesive can be based on at least one poly(meth)acrylate (e.g., is a (meth)acrylic pressure sensitive adhesive). Poly(meth)acrylic pressure sensitive adhesives can be derived from, for example, at least one alkyl (meth)acrylate ester monomer such as, for example, isooctyl acrylate, isononyl acrylate, 2-methyl-butyl acrylate, 2-ethyl-n-hexyl acrylate and n-butyl acrylate, isobutyl acrylate, hexyl acrylate, n-octyl acrylate, n-octyl methacrylate, n-nonyl acrylate, isoamylacrylate, n-decyl acrylate, isodecyl acrylate, isodecyl methacrylate, isobornyl acrylate, 4-methyl-2-pentyl acrylate and dodecyl acrylate; and at least one optional co-monomer component such as, for example, (meth)acrylic acid, vinyl acetate, N-vinyl pyrrolidone, (meth)acrylamide, a vinyl ester, a fumarate, a styrene macromer, alkyl maleates and alkyl fumarates (based, respectively, on maleic and fumaric acid), or combinations thereof. Exemplary optically clear pressure sensitive adhesive include those disclosed in U.S. Pat. Publ. Nos. 2006/0134362 (Lu et al.) and 2007/0141329 (Yang et al.). It is also within the scope of this invention to use optically clear adhesives that are not pressure-sensitive but are thermally activated. Furthermore, the optically clear adhesive component can be a single adhesive or the can be a combination of two or more optically clear adhesives. The adhesive, especially if it is a pressure-sensitive adhesive can be covered with a release liner as one of ordinary skill in the art would know. Exemplary optically clear adhesives include 3M OPTICALLY CLEAR ADHESIVES 8171 and 8172 as well as 3M LIQUID OPTICALLY CLEAR ADHESIVE 2175, available from 3M, St. Paul, Minn.

The provided optically transparent display filters include a multi-layer construction disposed either directly atop the support or, optionally, with a basecoat polymer layer between the support and the multi-layer construction. The multi-layer construction is disposed on the support on the side opposite the optically clear adhesive. The multi-layer construction includes a layer of metal oxide on the support. The metal oxide layer provides a barrier for the electrically-conductive layer and typically includes tin oxide (SnO₂). The metal oxide layer can include other species such as, for example, ZnSnO₃, Zn₂SnO₄, In₂O₃, ZnO, indium-tin-oxide, bismuth oxide, or combinations thereof. The metal oxide layer can be continuous or can be discontinuous (islands) and is typically from about 1 nm to about 10 nm in thickness. The metal oxide layer is typically sputtered from target under vacuum onto the support. In some embodiments, a transparent polymer layer can be deposited on the support prior to deposition of the metal oxide layer.

It can be advantageous to deposit a polycrystalline seed layer (nucleation layer) just prior to the deposition of the electrically conductive layer. This seed layer can be deposited directly upon the metal oxide layer. The use of zinc oxide or aluminum-doped zinc oxide (AZO) as a nucleation or seed layer on the basecoat layer or on organic layers contiguous to the metallic layers of the multi-layer construction used in the provided filter is described more fully in pending PCT Publ. No. WO 2008/083308 (Stoss et al.) which claims priority to U.S. Ser. No. 60/882,389 (Stoss), filed Dec. 28, 2006. Other materials useful as a nucleation or seed layer can be transparent conductive metal oxides (TCOs) such as indium oxide, indium-tin oxide, indium-zinc oxide, zinc oxide with other dopants such as gallium and/or boron, zinc-tin oxide (zinc stannates), or other TCOs, or combinations thereof.

The electrically-conductive layer can include a conductive elemental metal, a conductive metal alloy, a conductive metal oxide, a conductive metal nitride, a conductive metal carbide, or a conductive metal boride, or combinations of these materials and can be disposed directly upon the nucleation layer. Typical conductive metals include elemental silver, copper, aluminum, gold, palladium, platinum, nickel, rhodium, ruthenium, and zinc, with silver being especially useful. Alloys of these metals such as silver-gold, silver-palladium, silver-gold-palladium, or dispersions containing these metals in admixture with one another or with other metals also can be employed. TCO, such as indium-tin-oxide (ITO), indium-zinc-oxide (IZO), zinc oxide with or without dopants such as aluminum, gallium and boron, other TCOs, or combinations thereof can also be used as an electrically-conductive layer. In some embodiments, silver-gold alloy can be used as the electrically-conductive layer. Typically, silver-gold alloys that include from about 10 weight percent (wt %) to about 20 wt % gold have low electrical resistance and good corrosion resistance. An exemplary silver-gold alloy has about 15 wt % gold and about 85 wt % silver.

When conductive metal oxides are used as an electrically-conductive layer, the dielectric layer can have a resistivity that is at least about 100 times higher than the resistivity of the metal oxide. Typically the physical thickness of the electrically-conductive metallic or metal alloy layer or layers is from about 1 nm to about 50 nm, typically from about 5 nm to about 20 nm, whereas the physical thickness of TCO layers are from about 10 nm to about 500 nm, typically from about 20 nm to about 300 nm. Typically the electrically-conductive layer or layers are formed using techniques employed in the film metalizing art such as sputtering (e.g., planar or rotary magnetron sputtering), evaporation (e.g., resistive or electron beam evaporation), chemical vapor deposition (CVD), organometallic CVD (MOCVD), plasma-enhanced, assisted, or activated CVD (PECVD), ion sputtering, and the like. The electrically-conductive layer can provide a sheet resistance of less than 200 ohms/square, less than 100 ohms/square, or even less than 50 ohms/square to the filter.

The multi-layer construction can include a barrier layer in contact with the second surface of the electrically-conductive layer. The barrier layer can provide environmental protection to the electrically-conductive layer. The barrier layer can include chemical treatments of the electrically-conductive layer. Appropriate chemical treatments of metal layer surfaces and interfaces can help to improve corrosion resistance. Such treatments can be combined with adhesion promoting treatments using similar or different materials, and with plasma treatments, diffusion barriers, and nucleating layers. One or more corrosion inhibiting compounds can be included in the support, the polymers layers, the adhesive, and/or the abrasion-resistant coating. Improved corrosion resistance can be accomplished by exposing a metal surface or interface to a compound such as a mercaptan, a thiol-containing compound, an acid (such as carboxylic acids or organic phosphoric acids), a triazole, a dye, a wetting agent, an organic sulfide, or a disulfide, ethylene glycol bis-thioglycolate, a benzotriazole or one of its derivatives such as are described in U.S. Pat. Nos. 6,376,065 (Korba et al.), 7,148,360 (Flynn et al.), 2-mercaptobenzoxazole, 1-phenyl-1H-tetrazole-5-thiol, and glycol dimercaptoacetate as described in U.S. Pat. Nos. 4,873,139 (Kinosky), and 6,357,880 (Epstein et al.).

It has been found that a thin layer of material that can be similar in chemistry and application to the nucleation layer can act as a barrier layer to provide corrosion protection to the electrically-conductive layer. The barrier layer can include materials that are also useful as a nucleation layer such as ITO, IZO, zinc oxide with or without dopants such as aluminum, gallium, and boron, zinc-tin-oxide, ZnSnO₃, Zn₂SnO₄, In₂O₃, SnO₂, indium-tin-oxide, and combinations thereof. When the electrically-conductive layer includes silver, zinc oxide (ZnO) can be an effective barrier layer—even when it is non-continuous and applied in a manner identical to the nucleation layer. It is also contemplated that the barrier layer can be thicker, even significantly thicker, than the nucleation layer as long as it preserves transparency of the filter. The barrier layer of the provided filters can also include a transparent polymer layer in combination and adjacent to the metal oxide barrier layer described herein. In this embodiment, the transparent polymer layer can provide extra environmental protection. This layer can include any transparent polymers that have low moisture transmission rates and are typically crosslinked acrylic polymers.

The barrier layer can include a transparent organic polymer layer. Particularly useful barrier layers include a transparent organic polymer layer having a refractive index greater than about 1.49. The barrier layer can also be selected from polymers, plasma deposited oxide, organometallic materials and organic-inorganic hybrid materials. Plasma deposited oxide with some organic can be incorporated for optical layer and barrier layer as disclosed, for example in U.S. Pat. No. 6,696,157 (David et al.) and U.S. Pat. Publ. No. 2009/0169770 (Padiyath et al.). Typical polymers include conjugated polymers with an index greater than 1.55. For the provided optical filters, polymers, especially crosslinked polymers can meet the optical requirements of transparent EMI shielding, for example, when the filters are used as liquid crystal display panel filters. Examples of crosslinked polymers that are useful in the optical filters of this invention are disclosed in U.S. Pat. No. 6,818,291 (Funkenbusch et al.).

Useful crosslinked polymeric layers can be formed from a variety of organic materials. Preferably the polymeric layer is crosslinked in situ atop barrier layer. If desired, the polymeric layer can be applied using conventional coating methods such as roll coating (e.g., gravure roll coating) or spray coating (e.g., electrostatic spray coating), then crosslinked using, for example, UV radiation. Most preferably the polymeric layer can be formed by flash evaporation, vapor deposition and crosslinking of a monomer as described above for the basecoat layer. Volatilizable acrylamides (such as those disclosed in U.S. Pat. Publ. No. 2008/0160185 (Endle et al.)) and (meth)acrylate monomers are preferred for use in such a process, with volatilizable acrylate monomers being especially preferred. Fluorinated (meth)acrylates, silicon (meth)acrylates and other volatilizable, free radical-curing monomers can be used. Coating efficiency can be improved by cooling the support. Particularly preferred monomers include multifunctional (meth)acrylates, used alone or in combination with other multifunctional or monofunctional (meth)acrylates, such as phenylthioethyl acrylate, hexanediol diacrylate, ethoxyethyl acrylate, phenoxyethyl acrylate, cyanoethyl (mono) acrylate, isobornyl acrylate, isobornyl methacrylate, octadecyl acrylate, isodecyl acrylate, lauryl acrylate, β-carboxyethyl acrylate, tetrahydrofurfuryl acrylate, dinitrile acrylate, pentafluorophenyl acrylate, nitrophenyl acrylate, 2-phenoxyethyl acrylate, 2-phenoxyethyl methacrylate, 2,2,2-trifluoromethyl (meth)acrylate, diethylene glycol diacrylate, triethylene glycol diacrylate, triethylene glycol dimethacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, 1,6-hexanediol dimethacrylate, trimethylol propane triacrylate, ethoxylated trimethylol propane triacrylate, propylated trimethylol propane triacrylate, 2-biphenyl acrylate, tris(2-hydroxyethyl)-isocyanurate triacrylate, pentaerythritol triacrylate, phenylthioethyl acrylate, naphthloxyethyl acrylate, EBECRYL 130 cyclic diacrylate (available from Cytec Surface Specialties, West Paterson, N.J.), epoxy acrylate RDX80095 (available from Rad-Cure Corporation, Fairfield, N.J.), CN120E50 and CN120C60 (both available from Sartomer, Exton, Pa.), and mixtures thereof. A variety of other curable materials can be included in the crosslinked polymeric layer, e.g., vinyl ethers, vinyl naphthylene, acrylonitrile, and mixtures thereof.

Optionally, additional crosslinked polymeric spacing layers and additional electrically-conducting metallic layers can be applied atop the first metal layer. For example, stacks containing 3 metal layers or 4 metal layers (Fabry-Perot stacks) can provide desirable characteristics for some applications. In a specific embodiment, a film can have a stack containing 2 to 4 electrically-conducting metallic layers in which each of the electrically-conducting layers has a crosslinked polymeric spacing layer positioned between the metal layers. The optional crosslinked polymeric spacing layer can be formed from a variety of organic materials. The spacing layer can be crosslinked in situ after it is applied. In one embodiment, the crosslinked polymeric layer can be formed by flash evaporation, vapor deposition and crosslinking of a monomer as described above. Exemplary monomers for use in such a process include volatilizable (meth)acrylate monomers. In a specific embodiment, volatilizable acrylate monomers are employed. Suitable (meth)acrylates will have a molecular weight that is sufficiently low to allow flash evaporation and sufficiently high to permit condensation on the support. If desired, the spacing layer can also be applied using conventional coating methods such as roll coating (e.g., gravure roll coating) or spray coating (e.g., electrostatic spray coating), then crosslinked using, for example, UV radiation. The desired chemical composition and thickness of the spacing layer will depend in part on the nature of the support and the desired purpose of the film. Coating efficiency can be improved by cooling the support.

Exemplary monomers suitable for forming a spacing layer, a barrier layer, or a base coat layer include multifunctional (meth)acrylates, used alone or in combination with other multifunctional or monofunctional (meth)acrylates, such as hexanediol diacrylate, ethoxyethyl acrylate, phenoxyethyl acrylate, cyanoethyl (mono)acrylate, isobornyl acrylate, isobornyl methacrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2-phenoxyethyl methacrylate, 2,2,2-trifluoromethyl (meth)acrylate, diethylene glycol diacrylate, triethylene glycol diacrylate, triethylene glycol dimethacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, 1,6-hexanediol dimethacrylate, trimethylol propane triacrylate, ethoxylated trimethylol propane triacrylate, propylated trimethylol propane triacrylate, tris(2-hydroxyethyl)-isocyanurate triacrylate, pentaerythritol triacrylate, phenylthioethyl acrylate, naphthloxyethyl acrylate, IRR-214 cyclic diacrylate from UCB Chemicals, epoxy acrylate RDX80095 from Rad-Cure Corporation, and mixtures thereof. A variety of other curable materials can be included in the crosslinked polymeric layer, e.g., vinyl ethers, vinyl naphthylene, acrylonitrile, and mixtures thereof. The physical thickness of the crosslinked polymeric spacing layer will depend in part upon its refractive index and in part upon the desired optical characteristics of the film stack. For example, for use as an organic spacing layer in an infrared-rejecting Fabry-Perot interference stack, the crosslinked polymeric spacing layer typically will have a refractive index of about 1.3 to about 1.7, and an optical thickness of about 75 to about 200 nm, or about 100 to about 150 nm and a corresponding physical thickness of about 50 to about 130 nm, or about 65 to about 100 nm.

The spacing layer, a barrier layer, or a base coat layer, when it is a cross-linked polymer can be applied using conventional coating methods such as roll coating (e.g., gravure roll coating) or spray coating (e.g., electrostatic spray coating), and then can be crosslinked using, for example, electron beam or UV radiation. Other conventional coating methods include, for example, solution casting, ink-jet printing, aerosol spraying, dip coating, and spin coating. Preferred methods are vacuum deposition techniques including, plasma polymerization, chemical vapor deposition (CVD, MOCVD, PECVD), vacuum sublimation, pulse laser deposition (PLD), pulse laser evaporation, polymer multilayer process (PML), liquid multilayer process (LML), and plasma polymer multiplayer process (PPML). The methods used for depositing the basecoat layer outlined above can be utilized for the organic layers.

In some embodiments, it is preferable to use a dielectric layer that includes a crosslinked acrylate polymer that has an index of refraction greater than 1.49, greater than 1.55, or even greater than 1.60. The use of an organic layer with a refractive index greater than 1.49 can improve the optical transmission of the filter and provide antireflection properties to the filter with some constructions. The use of high index polymers is discussed in more detail below for certain embodiments of the provided optical filters. Preferred polymers include conjugated polymers. Acrylates that can be used to produce high index organic layers can include a thioacrylate or a phenyl acrylate. Thioacrylate and phenyl acrylate monomers can be used to make curable acrylate compositions that have an index of refraction of greater than or equal to about 1.54, greater than or equal to about 1.56, greater than or equal to about 1.58, or even greater than or equal to about 1.60. A particularly useful thioacrylate is phenylthioethyl acrylate. A particularly useful phenyl acrylate is 2-biphenyl acrylate. Curable (meth)acrylate compositions with refractive index above 1.49 are disclosed, for example, in U.S. Pat. No. 6,833,391 (Chisholm et al.). In other embodiments, it is preferable to use a layer that includes a polymer that has an index of refraction that is low (i.e., lower than about 1.47 or even lower than about 1.40). Examples of such materials include, for example, polymers that contain substantial amounts of fluorine such as those disclosed in U.S. Pat. Appl. No. 2006/0148996 (Coggio et al.). Other examples of low index, transparent polymers include silicone polymers. Any transparent, low index materials can be useful to make embodiments of the provided filters. The use of low index polymers is discussed in more detail below for certain embodiments of the provided optical filters.

The optically transparent display filter can, optionally, include a dielectric basecoat layer disposed on the support. Basecoat layers that include crosslinked acrylate polymers, are especially preferred. Most preferably, the basecoat layer can be formed by flash evaporation and vapor deposition of a radiation-crosslinkable monomer (e.g., an acrylate monomer), followed by crosslinking in situ (using, for example, an electron beam apparatus, UV light source, electrical discharge apparatus or other suitable device), as is well known to those skilled in the art. If desired, the basecoat can also be applied using conventional coating methods such as roll coating (e.g., gravure roll coating) or spray coating (e.g., electrostatic spray coating), then crosslinked using, for example, UV radiation. The desired chemical composition and thickness of the basecoat layer will depend in part on the nature of the support. For example, for a PET support, the basecoat layer preferably is formed from an acrylate monomer and typically will have a thickness from about a few nanometers up to about 10 micrometers (μm).

The adhesion of the electrically-conductive layer (including the nucleation layer) of the multi-layer construction to the support or the basecoat layer, or an abrasion-resistant layer (hardcoat), if present, can be further improved by including an adhesion-promoter to the support or the basecoat layer or the hardcoat. The adhesion-promoting layer can be, for example, a separate polymeric layer or a metal-containing layer such as a layer of a metal, an alloy, an oxide, a metal oxide, a metal nitride, or a metal oxynitride such as those disclosed in U.S. Pat. Nos. 3,601,471 (Seddon) or 3,682,528 (Apfel et al.) and include, for example, Cr, Ti, Ni, NiCr alloys, or ITO. The adhesion-promoting layer can have a thickness of from a few nanometers (e.g., 1 nm or 2 nm) to about 10 nm, and can be thicker if desired. The interlayer adhesion-promoting layers that can be utilized may also act as diffusion barriers. Examples of adhesion promotion layers with diffusion barrier properties include TCOs such as ITO, aluminum, aluminum oxide, copper, copper oxides, silicon, silicon oxides, titanium, titanium oxides, titanium nitride, titanium tungstate, tantalum, tantalum oxides, tantalum nitride, chromium, chromium oxides, and silicon nitrides. Suitable adhesion-promoting additives include mercaptans, thiol-containing compounds, acids (such as carboxylic acids or organic phosphoric acids), triazoles, dyes, and wetting agents. Epoxy acrylates such as CN120E50 and CN120C60, ethylene glycol bis-thioglycolate, and phenylthioethyl acrylate (PTEA) are particularly preferred additives. The additive preferably is present in amounts sufficient to obtain the desired degree of increased adhesion, without causing undue oxidation or other degradation of electrically-conductive layers. Corona treatment or plasma discharge can also be used to increase adhesion.

The smoothness, continuity, and conductivity of the multi-layer construction and its adhesion to the support or basecoat layer can be enhanced by appropriate pretreatment of the support. A typical pretreatment regiment involves electrical discharge pretreatment of the support in the presence of a reactive or non-reactive atmosphere (e.g., plasma, glow discharge, corona discharge, dielectric barrier discharge or atmospheric pressure discharge); chemical pretreatment; flame pretreatment; or application of a nucleating layer such as the oxides and alloys described in U.S. Pat. Nos. 3,601,471 and 3,682,528 and PCT Publ. No. WO 2008/083308 (Stoss et al.). These pretreatments can help ensure that the surface of the support will be receptive to the subsequently applied metal layer. Plasma pretreatment is particularly preferred for certain embodiments. Similar pretreatments or application of a nucleating layer are typically used on each polymer spacing layer before deposition of each electrically-conducting layer.

Various functional layers or coatings can be added to the provided optically transparent display filters to alter or to improve their physical or chemical properties, particularly when applied to the surface of the filter or to the opposite side of the support. Such layers or coatings can include, for example, low friction coatings (see for example, U.S. Pat. No. 6,744,227 (Bright et al.)) or slip particles to make the filter easier to handle during manufacturing; particles to add abrasion-resistance or diffusion properties to the filter or to prevent wet-out or Newton's rings when the film is placed next to another film or surface; antireflection layers to prevent glare when the optically transparent display filter is applied to the face of an information display; optical polarizers, antistatic coatings; abrasion resistant or hardcoat materials; anti-fogging materials; magnetic or magneto-optic coatings or films; adhesives such as pressure-sensitive adhesives or hot melt adhesives especially if they are optically clear adhesives such as those disclosed, for example, in U.S. Pat. No. 6,887,917 (Yang et al.), U.S. Pat. Publ. No. 2006/0134362 (Lu et al.) or other available from, for example, 3M Company (St. Paul, Minn.), Loctite Corporation (Rocky Hill, Conn.), or Dymax Corporation (Torrington, Conn.); primers to promote adhesion to adjacent layers; low adhesion backsize materials for use when the filter is to be used in adhesive roll form; liquid crystal panels; electrochromic or electroluminescent panels; photographic emulsions; prismatic films and holographic films or images. Additional functional layers or coatings are described, for example, in U.S. Pat. Nos. 6,352,761; 6,641,900; 6,830,713; 6,946,188; and 7,150,907 (all Hebrink et al.); 6,368,699 and 6,459,514 (both Gilbert et al.); 6,737,154 (Jonza et al.); 6,783,349 (Neavin et al.); and 6,808,658 (Stover). The functional layers or coatings can also include anti-intrusion, or puncture-tear resistant films and coatings, for example, the functional layers described in U.S. Pat. No. 7,238,401 (Dietz). Additional functional layers or coatings can include vibration-damping film layers such as those described in U.S. Pat. Nos. 6,132,882 (Landin et al.) and U.S. Pat. No. 5,773,102 (Rehfeld), and barrier layers to provide protection or to alter the transmissive properties of the film towards liquids such as water or organic solvents or towards gases such as oxygen, water vapor or carbon dioxide. Additionally, self-cleaning layers, such as fluorocarbon or fluoropolymer layers known to those skilled in the art can be added. These functional components can be incorporated into one or more of the outermost layers of the optically transparent display filter, or they can be applied as a separate film or coating.

Appropriate chemical treatments of metal layer surfaces and interfaces can help to improve corrosion resistance. Such treatments can be combined with adhesion promoting treatments using similar or different materials, and with plasma treatments, diffusion barriers, and nucleating layers. One or more corrosion inhibiting compounds can be included in the support, the polymers layers, the adhesive, and/or the abrasion-resistant coating.

For some applications, it may be desirable to alter the appearance or performance of the optically transparent display filter, such as by laminating a dyed film layer to the filter, applying a pigmented coating to the surface of the filter, or including a dye or pigment in one or more of the materials used to make the filter. The dye or pigment can absorb in one or more selected regions of the electromagnetic spectrum, including portions of the infrared, ultraviolet or visible spectrum. The dye or pigment can be used to complement the properties of the film, particularly where the film transmits some wavelengths while reflecting others. A particularly useful pigmented layer that can be employed in the films or pre-laminates of the invention is described in U.S. Pat. No. 6,811,867 (McGurran et al.). This layer can be laminated, extrusion coated or coextruded as a skin layer on the film. The pigment loading level can be varied between about 0.01 weight percent (wt %) and about 1.0 wt % to vary the visible light transmission as desired. The addition of a UV absorptive cover layer can also be desirable to protect any inner layers of the film that may be unstable when exposed to UV radiation. The optically transparent display filter can also be treated with, for example, inks or other printed indicia such as those used to display product identification, orientation information, advertisements, warnings, decoration, or other information. Various techniques can be used to print on the filter, such as, for example, screen printing, inkjet printing, thermal transfer printing, letterpress printing, offset printing, flexographic printing, stipple printing, laser printing, and so forth, and various types of ink can be used, including one and two component inks, oxidatively drying and UV-drying inks, dissolved inks, dispersed inks, and 100% solids ink systems.

The provided optical filters can have performance properties that can allow them to simultaneously reflect or transmit various portions of the electromagnetic spectrum. They can be designed to transmit at least 80%, at least 85%, at least 90%, or even at least 92% of the average actinic radiation between the wavelengths of 450 nm and 650 nm. In addition, they can also be designed to reflect less than 10%, less than 8%, less than 5%, or less than 3% of the actinic radiation between the wavelengths of 450 nm and 650 nm. Typically transmission in the electromagnetic spectrum is measured at 550 nm. In addition, the filters can be designed to block the passage of harmful electromagnetic interference (EMI) emission to or from display devices. The filters can provide EMI shielding of radio frequency waves and microwaves of at least 10 dB, at least 15 dB, at least 20 dB, at least 25 dB, at least 30 dB, at least 35 dB, at least 40 dB, or even at least 45 dB. These ranges are well-known by those skilled in the art and are typically regulated. The filters can also block infrared radiation by reflection of more than 95%, more than 97%, more than 98%, or more than 99% of the average near infrared radiation between 800 nm and 2500 nm.

Optically transparent display filters with low visible reflectance are also especially desirable to improve the display performance. Conceptually, the visible reflectance can be lowered by adding an antireflection (AR) coating to the outer layers of the multi-layer construction described above. The simplest form of antireflection coating is a single layer, where the refractive index and optical thickness of the AR layer is chosen to match the optical admittance of, for example, the metal layer to the admittance of the incident (neighboring) medium. For the provided optically transparent display filter, the AR function may be provided by the optional basecoat layer and/or the topcoat (the last dielectric layer of the multi-component film, and/or additional layers). The optical filter can also be designed to provide electromagnetic interference (EMI) shielding in the radio frequency and microwave region of the EM spectrum. Generally, electrically conductive films can be used to provide EMI shielding. Shielding Effectiveness (SE) of an electric field is correlated with the film sheet resistance, and in far field can be approximated using the good conductor approximation:

SE (dB)=20 log(1+Zₒ/2Rₛ)

where Zₒ and Rₛ are the impedance of free space (377Ω) and film sheet resistance, respectively. In many display applications the location of the EMI shield is in the near field for high frequencies. In such cases, the SE achieved is greater than the far field value calculated from the formula above. Therefore, using the far field value of SE is always a conservative approximation. Low reflection optical filters with EMI shielding can be designed using the above design guidelines. However, all the properties such as EMI shielding, transmission, and reflectance are dynamically related. Designing for higher EMI shielding performance requires the filter to have a certain electrical conductivity, which correlates with the overall number and thickness of conductive layers. At the same time, electrically conductive materials such as metals are likely to have high optical loss. As a result, increasing the conductivity by increasing the number and/or thickness of the layers can result in lower transmission. Designing for low reflectance has to take into account all of the layers of the construction rather than just the basecoat and topcoat “AR coatings” as well as all other requirements, such as designing for wide-angle viewing performance. The challenges of designing to meet all attributes such as EMI shielding, high transmission and low reflection over a certain viewing angle are significant. In addition, the results are highly dependent upon the deposition process, since the material properties achieved are very process-dependent. For example, the electrical and optical properties of the conductive layers such as Ag or ITO can be significantly different depending upon process conditions. Controlling these properties is critical to the construction of the interference-type optical filter provided herein.

The use of a silver-gold alloy as the electrically-conductive coating can enhance antireflective properties of optical filters due to the partial absorption of the visible spectrum due to the gold content. Thus, by including gold in the coatings additional absorption of visible light results in less reflectivity.

Good design requires theoretical treatments of the characteristics of electromagnetic wave propagation, which is complicated and usually requires computation methods, which typically involve solving Maxwell's equations with appropriate boundary conditions for an assembly of thin films. The provided optically transparent display filters can be used to modify the radiation emitted from an electronic display device such as a plasma display panel, a liquid crystal display panel (LCD), or other devices such as the displays on mobile hand-held phones. Optically transparent display filters, when used external to the devices, can block harmful radiation being emitted from the devices and improve the visual characteristics of the desired visible radiation including increasing the contrast of the visual display. Alternatively, the provided optically transparent display filters can protect some electronic devices from radiation external to the device. For example, touch screen devices can be temporarily “desensitized” by exposure to stray electromagnetic radiation (noise) external to the device. An optically transparent display filter can be located between the touch screen panel and the electronic device to counteract this desensitization.

It is contemplated that the EMI shielding can provide protection to the user of an electronic display device that meets the Specific Absorption Rate (SAR) requirements of governmental agencies. For example, currently the Federal Communications Commission of the United States has set a SAR level of less than 1.6 Watts/kg (W/kg) of radiation between 100 kHz and 10 GHz per 1 g of tissue for mobile phones. The European Union has set a limit of 2 W/kg over 10 g of human tissue. It is contemplated that an electrically-conducting layer can be added to the provided filters to reach these or future limits.

The provided transparent conductor can be used as a “guard” or “shield” for the touch panel application with consideration of optical loss, and signal enhancement into the design. EMI shielding employs the Faraday cage concept, that the shielding film needs to form a complete electrical enclosure with the metal chassis of and electronic device and to be electrically grounded to that chassis. For example, EMI shielding between a touch panel and a display panel, utilizing a transparent conductor film can form a Faraday cage with the metal chassis of the display panel. Transparent conductor guards can help to contain or concentrate the electromagnetic field from a target surface of an electronic device, such as a touch-sensitive panel, thereby increasing the sensitivity of the device. To create a guard, the back and sides of the touch sensing area can be surrounded by another conductor that is kept at the same voltage as the sensing area itself. When the voltage is applied to the sensing area, the exact same voltage is also applied to the guard. Because there is no difference in voltage between the sensing area and the guard, there is no electric field between them. Any other conductors behind the guard can form an electric field with the guard instead of the sensing area. Only the unguarded front of the sensing area can form an electric field with the target touch.

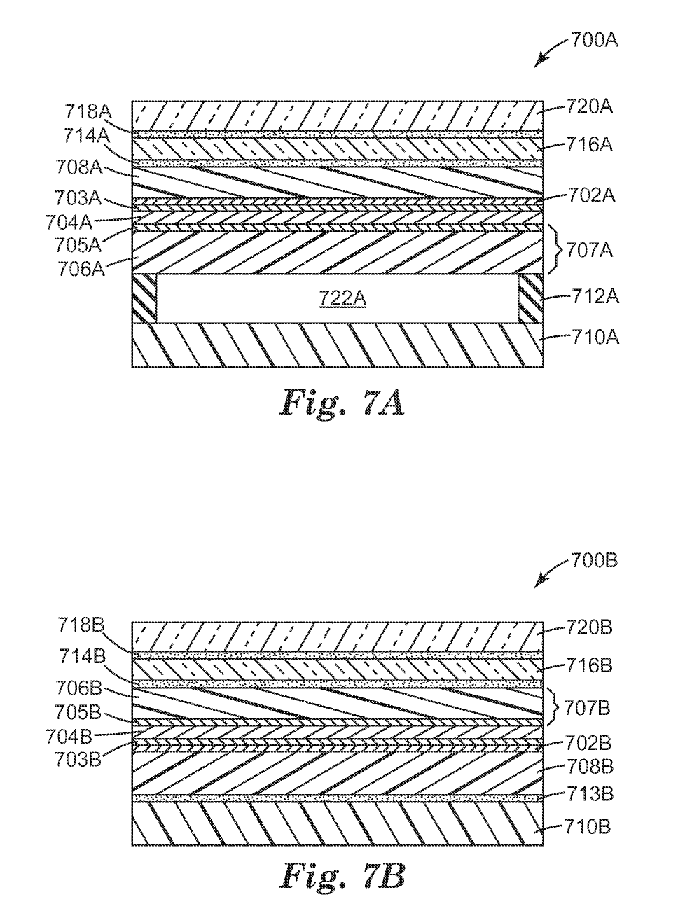

The provided optical filters can be used to provide EMI shielding capacitive touch sensors for electronic devices. An electronic device having a display, such as an LCD display, can have an EMI shielding optical filter optically attached using an optically clear adhesive as illustrated in FIG. 7B. The barrier layer for the EMI shielding layer (that can include a crosslinked polymer layer can act as a dielectric for the deposition of two more optically-clear electrically-conductive metal or metal alloy layers. These layers can be patterned—one in an x-plane orientation and a second in a y-plane orientation—to produce a multilayer stack which includes a continuous EMI shielding layer, an x-plane patterned capacitive layer, and a y-lane patterned capacitive layer. When the electrically-conductive layers are very thin (for example, by using the provided optical filters) and made of metal or metal alloy—typically silver-gold alloy—highly sensitive capacitive touch plates for LCD devices can be produced. Touch screens having discrete touch-sensitive areas are disclosed, for example, in U.S. Pat. Publ. No. 2009/0146970 (Lowles et al.) and U.S. Pat. No. 6,188,391 (Seely et al.).

The transparent electrically-conductive metal or metal alloy layers can be patterned using a variety of techniques including laser ablation, dry etching, and wet etching. In some embodiments, the provided optical shielding filters can be patterned by providing a resist with a pattern over the barrier layer that is protecting the electrically-conducting metal or metal alloy layer. The resist can include hydrocarbon waxes, positive photoresists, negative photoresists or any other resist or masking known to those of ordinary skill in the art of patterning and masking. After applying the resist the filter can be immersed in an etching tank and exposed to an etching solution to remove the exposed metal or metal alloy layer. Useful etchants include, for example, ferric chloride and potassium permanganate solutions. Typically the filter can be exposed to the etchant for about 1-5 minutes. After exposure, the filters can be rinsed with water, dried, and used in further operations.

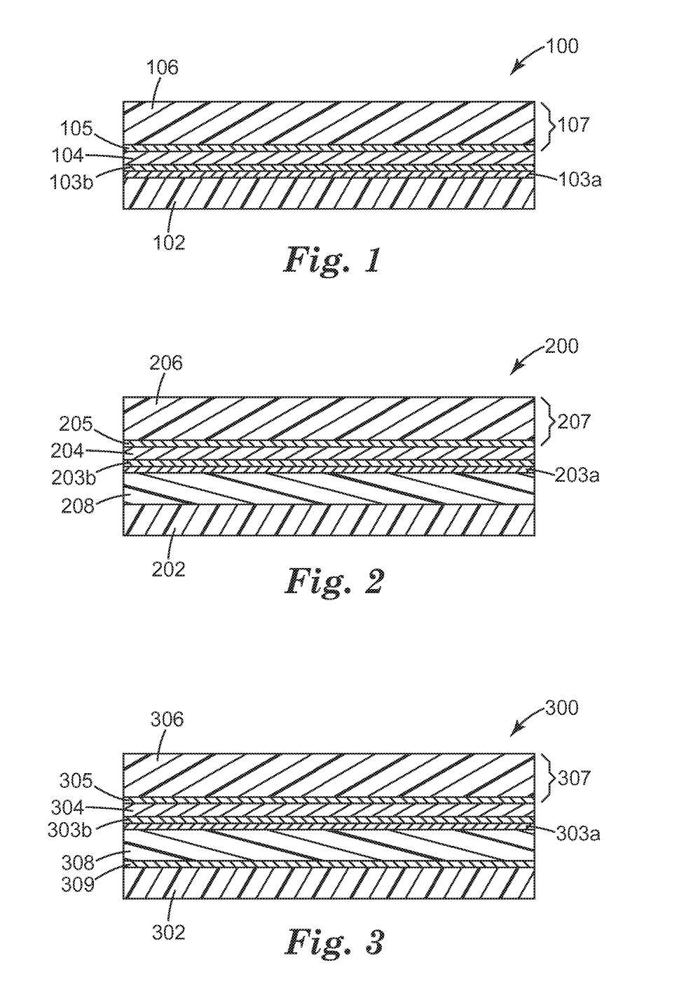

FIG. 1 is an illustration of one embodiment of provided optical filters. Optical filter 100 has support 102 that is a film of polyester terephthalate (PET) having a refractive index of 1.65. Metal oxide layer 103a has been deposited on the support followed by polycrystalline seed layer 103b which has been directly upon the metal oxide layer. The polycrystalline seed layer can be discontinuous. Transparent electrically-conductive layer 104 (silver-gold alloy) has been deposited directly upon the polycrystalline seed layer. Transparent electrically conductive layer 104 is passivated by deposition of barrier layer 107, which in this embodiment, includes metal oxide layer 105 and crosslinked acrylic polymer layer 106. Metal oxide capping layer 105 can be discontinuous and similar in thickness to polycrystalline seed layer 103b or can be thicker and continuous. Details of the barrier layer have been discussed above. In the embodiment illustrated in FIG. 1 reflectivity between layers of the filters is reduced if the refractive index and thickness are chosen to optically match the electrically-conducting layer 104. Metal oxide layer 105 is very thin compared to the electrically-conductive layer in this embodiment.

FIG. 2 is another embodiment of provided optical filters in which optical filter 200 includes an additional polymer layer 208 (polymer basecoat layer) sandwiched between support 202 and the multi-layer construction that includes metal oxide layer 203a, polycrystalline seed layer 203b, transparent electrically-conductive layer 204, and barrier layer 207 (which includes metal oxide capping layer 205 and crosslinked acrylic polymer layer 206. Polymer basecoat layer 208 has been added to the embodiment shown in FIG. 2 to optically match the electrically conductive layer as in FIG. 1. If electrically-conductive layer 204 is a metal such as silver, gold, or copper, with a low (<1) real part of the refractive index, then polymer 208 should have a high index optically match electrically-conductive layer 204 (neglecting the optical contribution of the very thin barrier layer 205) and to raise the effective refractive index of layer 204 to more closely match support 202. The ideal polymer layer 208 has a refractive index as high or higher than polymer layer 206, which is also present in this embodiment. In another embodiment, also illustrated by FIG. 2, polycrystalline seed layer 203 can be made thicker so as to form a matching optical pair with polymer 208. In this embodiment the layers 203a, 203b and 208 taken together can have an effective index of refraction greater than that of support 202.

FIG. 3 is an illustration of another embodiment 300 of provided optical filters and differs from the embodiments illustrated in FIG. 2 in that there is an additional barrier layer 309 between the support 302 and the polymer basecoat layer 308. In one such embodiment, support 302 has layers 309, 308, 303a and 303b that act as a symmetrical four-layer equivalent index optical layer disposed upon the support. In an exemplary embodiment, layers 303a, 303b, and 309 are continuous ZnO layers and layer 308 is a high index acrylic polymer. For a low index metal electrically-conducting layer 304, the symmetrical four-layer equivalent index optical layer typically has an equivalent index greater than that of PET. Transparent electrically-conductive layer 304 and barrier layer 307, made up of metal oxide capping layer 305 and crosslinked polymer 306 are disposed on top of the symmetrical four-layer equivalent optical layer to provide extra optical effects and environmental protection.

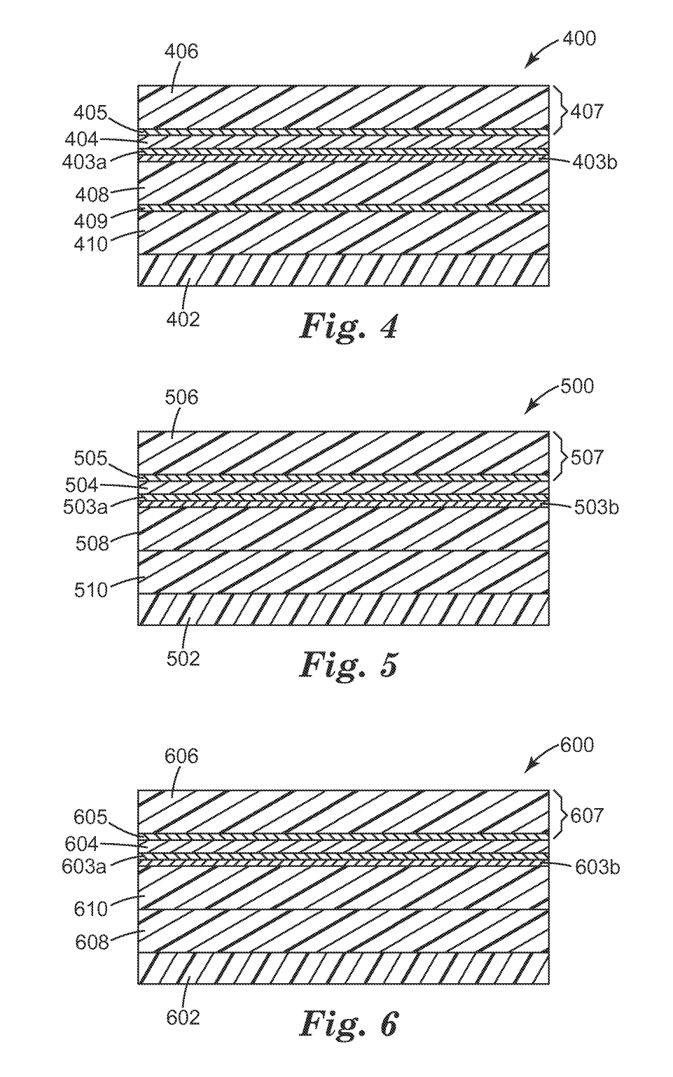

FIG. 4 illustrates an embodiment 400 of provided optical filters in which five layers, polymer 410, additional metal oxide barrier layer 409, basecoat polymer 408, metal oxide layer 403a, and polycrystalline seed layer 403b perform optical matching between support 402 and transparent electrically-conducting layer 404. As in most other embodiments, transparent electrically conducting layer 404 is protected by barrier layer 407 that includes metal oxide capping layer 405 and crosslinked polymer 406. In an additional embodiment of the provided optical filters that can also be illustrated by FIG. 4, basecoat polymer 410 which is in contact with support 402, can be deposited at a half wave optical thickness and the elements 409, 408, 403a, and 403b can form a four-layer optical layer that has an equivalent index of refraction that is preferably higher than that of support 402.

FIG. 5 illustrates an embodiment 500 in which two basecoat polymers—508 with a high index of refraction and 510 with a low index of refraction are disposed on support 502. In this embodiment metal oxide layer 503a and polycrystalline seed layer 503b allow for the deposition of transparent electrically-conductive layer 504 that is protected by barrier layer 507 (a combination of metal oxide layer 505 and crosslinked polymer 506) as in previous embodiments. Low index polymer 510 has a thickness of about a quarter wave optical thickness and high index polymer 508, metal oxide layer 503a, and polycrystalline seed layer 503b function as a three layer equivalent optical matching layer.

FIG. 6 illustrates an embodiment 600 schematically very similar to that of FIG. 5 except that transparent electrically-conductive layer 604 has a high refractive index. Basecoat polymer 608, which is adjacent and in contact with support 602, has a refractive index different from the refractive index of low index polymer 610. The combination of these two polymer layers function as a two-layer equivalent optical matching layer. Metal oxide layer 603a, polycrystalline seed layer 603b, transparent electrically-conductive layer 604 are deposited on top of polymer 610 and then barrier layer 607 (which includes metal oxide layer 605 and polymer layer 606) finishes the filter construction.

FIG. 7A illustrates an embodiment 700A of a touch-sensitive electronic device that includes a provided optical filter. The device includes LCD display 710A. A multi-layer stack is disposed on the LCD display face using rubber gaskets 712A that provide air space 722A over most of the LCD display face. The filter includes support 706A upon which is disposed a multi-layer construction that includes basecoat polymer layer 708A, metal oxide layer 703A, polycrystalline seed layer 703A, transparent electrically-conducting layer 704A, and barrier layer 707A (which includes metal oxide capping layer 705A, and polymer layer 706A. On top of the multi-layer construction is touch-sensitive glass 716 that is bonded to the top polymer layer 708A of the multi-layer construction with optically clear adhesive 714A. Finally glass 720A is bonded to touch glass 716A with an additional layer of optically clear adhesive 718A.

FIG. 7B illustrates another embodiment 700B of a touch-sensitive electronic device that includes a provided optical filter. The device includes LCD display 710B. A multi-layer filter is disposed directly upon the LCD display face using optically clear adhesive 713B. The filter comprises a multi-layer construction that includes basecoat polymer layer 708B, metal oxide layer 708B, polycrystalline seed layer 702B, transparent electrically-conducting layer 704B, barrier layer 707B (which includes metal oxide capping layer 705B and crosslinked polymer layer 706B. The arrangement of the multi-layer construction in embodiment 700B is reversed from that in embodiment 700A. The illustrated embodiment in 700B enables capacitive coupling for capacitive touch screen displays. It is to be understood that either configuration of the multi-layer construction can be used in either embodiments 700A or 700B. On top of the multi-layer construction is touch-sensitive glass 716B that is bonded to the top polymer layer 708B of the multi-layer construction with optically clear adhesive 714B. Finally glass 720B is bonded to touch glass 716B with an additional layer of optically clear adhesive 718B.

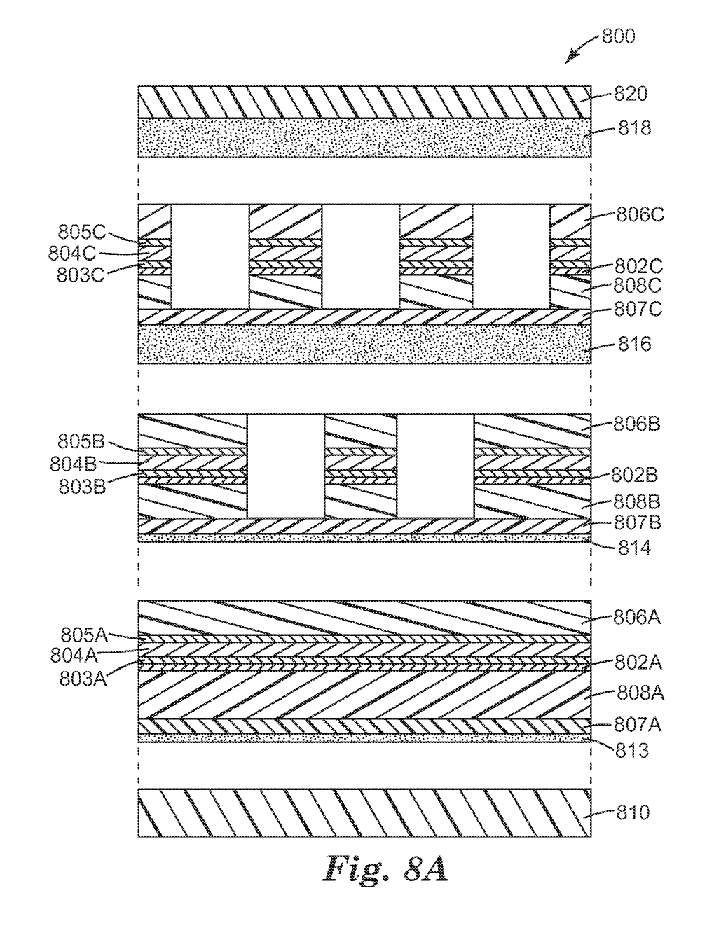

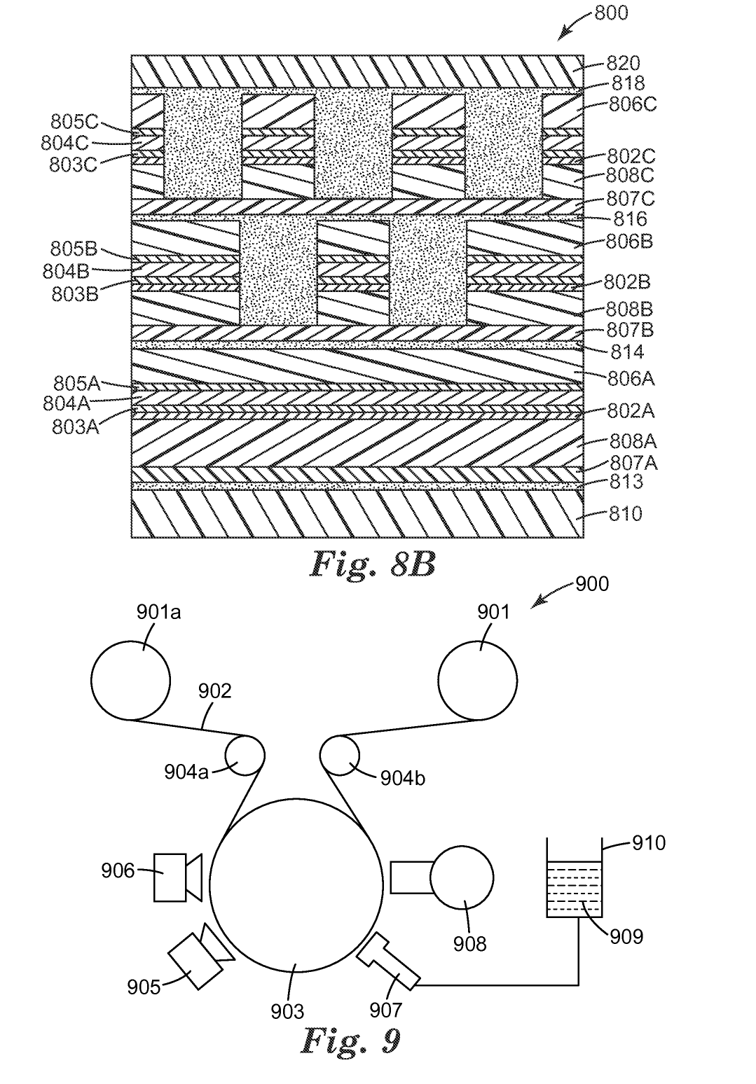

FIGS. 8A and 8B illustrate yet another embodiment 800 of a capacitive touch-sensitive electronic device that includes provided optical filters. The electronic device depicted in FIG. 8 is very similar to that depicted in FIG. 7B. Turning first to FIG. 8A which is an exploded view of the components of FIG. 8B. Device 800 includes LCD display 810. Directly above LCD display 810 is one embodiment of a provided optical filter. This embodiment includes transparent support 807A and basecoat polymer layer 808A which is disposed directly upon polyester carrier 807A. Optically clear adhesive 813 has been laminated to the side of polyester carrier 807A opposite basecoat polymer layer 808A. An EMI shielding stack is disposed upon polymer layer 808A and includes metal oxide layer 802A, polycrystalline seed layer 803A, transparent electrically-conductive layer 804A, metal oxide capping layer 805A, followed by crosslinked acrylic polymer layer 806A which functions as a barrier and a dielectric layer.

A second provided optical filter includes transparent support 807B, basecoat polymer 808B, metal oxide layer 802B, second polycrystalline seed layer 803B, second transparent electrically-conductive layer 804B, which is patterned and forms one of two capacitive touch-sensitive layers (oriented along the x and y planes) and is disposed upon second seed layer 803B. Patterned electrically conductive layer 804B is passivated by second metal oxide capping layer 805B and second crosslinked acrylic polymer layer 806B. Optically clear adhesive 816 is laminated to transparent support 807B on the side opposite basecoat polymer layer 808B. The patterning of this second filter has been done through a mask by patterned etching through layer 806B. The etching has removed exposed portions of layers 806B, 805B, 804B, 803B, and 802B but does not effect transparent support 807B.

A third provided optical filter includes transparent support 807C, basecoat polymer 808C, metal oxide layer 802C, second polycrystalline seed layer 803C, second transparent electrically-conductive layer 804C, which is patterned and forms the other of two capacitive touch-sensitive layers (oriented along the x and y planes) and is disposed upon second seed layer 803C. Patterned electrically conductive layer 804C is passivated by second metal oxide capping layer 805C and second crosslinked acrylic polymer layer 806C. Optically clear adhesive 814 is laminated to transparent support 807C on the side opposite basecoat polymer layer 808C. The patterning of this second filter has been done through a mask by patterned etching through layer 806C. The etching has removed exposed portions of layers 806C, 805C, 804C, 803C, and 802C but does not effect transparent support 807C. 820 is a glass touch surface that has optically clear adhesive 818 laminated to it.

In FIG. 8B the layers and embodiments depicted and described in FIG. 8A have been all laminated together since each layer and embodiment includes an optically clear adhesive. Optically clear adhesive 816 has flowed into the etched recesses of the second multilayered optical filter (depicted by the “B” numbers) to fill in the gaps and provide an optically clear layer (with no air gaps). Similarly, optically clear adhesive 818 has flowed into the etched recesses of the second multilayered optical filter (depicted by the “C” numbers) to fill in the gaps and provide an optically clear layer (with no air gaps).

The electrically-conductive metal or metal alloy layers can have electrode leads attached to them that either can lead to ground (as in the case of the electrically-conductive continuous layers that function as an EMI shield), or can lead to other electronic circuits (in the case of the patterned electrically-conductive layers that function as x-plane or y-plane capacitive touch sensor plates. These leads, grounds, and circuits are not shown on the accompanying set of figures for simplicity.

Combinations of patterned optical filters and unpatterned optical filters are contemplated by this disclosure. In some embodiments, two patterned touch sensors such as those depicted as the second provided optical filter and the third optical filter can be laminated directly to an electronic device or onto another EMI shielding filter that is known to those of ordinary skill in the art. In other embodiments, the provided EMI shielding optical filter (depicted by the provided unpatterned optical display filter with “A” numbers) can be used alone or with other embodiments of touch-sensitive substrates.

An apparatus 900 that can conveniently be used to manufacture films of the present invention is illustrated by the schematic in FIG. 9. Powered reels 901 and 901a move supporting web 902 back and forth through apparatus 900. Temperature-controlled rotating drum 903 and idlers 904a and 904b carry web 902 past metal/metal oxide sputter applicator 905, plasma treater 906, monomer evaporator 907 and UV light station (curing station) 908. Liquid monomer 909 is supplied to evaporator 907 from reservoir 910. Successive layers can be applied to web 902 using multiple passes through apparatus 900. Apparatus 900 can be enclosed in a suitable chamber (not shown in FIG. 9) and maintained under vacuum or supplied with a suitable inert atmosphere in order to discourage oxygen, water vapor, dust and other atmospheric contaminates from interfering with the various plasma, monomer coating, curing and sputtering steps. Vacuum is required for the sputtering step—the other processes can preferably be run in vacuum but could be run at other pressures.

The provided optically transparent display filters are useful in combination with electronic displays such as liquid crystal displays, OLED displays, or plasma displays that can be used on electronic devices such as hand-held mobile phones. The filters can modify the radiation that is emitted from these devices so as to block the transmission of unwanted or harmful wavelengths and modify the selection of wavelengths allowed to be transmitted. For example, in some embodiments the filters can block the transmission of EMI radiation and can be designed to allow visible radiation to be transmitted but not infrared.

In some embodiments the provided display filter can be integrated into touch-sensitive devices as depicted, for example, in FIGS. 7A, 7B and 8. Touch-sensitive devices can be resistive or capacitive. The provided display filters are particularly useful when a capacitive touch-sensitive support is used to provide touch sensitivity since the filters protect the glass from unwanted radiation generated by the device which can also erroneously interact with the touch-sensitive layer.

### EXAMPLES

TABLE 1
Materials for Examples

| Identification | Description |
|---|---|
| BPDA-1 | 2,2′-diethoxy-biphenyl diacrylate, disclosed in Preparatory |
| | Examples 1 and 2 on page 26-27 of PCT Pat. Publ. No. |
| | WO 2008/112451 (Invie et al.) |
| CN147 | An acidic acrylate oligomer available under the trade |
| | designation “CN147” from Sartomer Company, Inc., |
| | Exton, Pennsylvania. |
| PTEA | Phenylthioethyl acrylate available under the trade |
| | designation “PTEA” from Bimax Chemicals Ltd., |
| | Cockeysville, Maryland. |
| IRGACURE | A photoinitiator available under the trade designation |
| 2022 | “CIBA IRGACURE 1022” from Ciba Holding Inc., |
| | Tarrytown, New York. |
| Formulation | An acrylate monomer solution having 83.5 parts (by wt.) |
| 1 | BPDA-1, 6 parts CN147, 8 parts PTEA and 2.5 parts |
| | IRGACURE 2022 |

A multi-zone vacuum chamber comprising a roll to roll web handling system which allows for sequential coating and/or treatment processes; including plasma treatment, e-beam treatment, sputter coating and vapor coating; was used to prepare all examples and comparative examples. Generally, sequential coating was used to deposit two different materials during a single pass through the chamber. Unless otherwise noted, the web was run in the forward direction. A schematic of the coating system is shown in FIG. 9 and is essentially the same as that disclosed, for example, in FIG. 6A of U.S. Pat. No. 7,351,479 (Fleming et al.).

### Test Method 1: Optical Analysis

Measurements were made on a BYK Gardner TCS PLUS Spectrophotometer Model 8870 (BYK Gardner Inc., USA) in accordance with ASTM D1003, E308, CIE 15.2. The percent transmittance was measured from 380 to 720 nm using d/8° geometry. Reflectance was measured similarly with specular reflection included.

### Test Method 2: Electrical Analysis

The surface resistivity was measured by Eddy current method using Model 727R Benchtop Conductance Monitor, available from Delcom Instruments Inc., Prescott, Wis.

### Test Method 3: Shielding Effectiveness

Shielding effectiveness for a frequency range of 100 MHz to 1.5 GHz was characterized in accordance with ASTM D-4935.

### Test Method 4: Reliability Analysis

Film samples, approximately 5.1 cm×5.1 cm, were placed in controlled temperature and humidity chambers. A set of samples was placed in a chamber set at 65° C. and 90% relative humidity (RH) for 3 days. Another set of samples was placed in a chamber set at 85° C. and 85% RH for 3 days. Samples were visually inspected for defects.

### Example

### Ag/Au Conductive Layer with SnO₂ Underlayer and ZnO Seed Layer

A polyester web, unprimed, with a 2 mil (0.05 mm) thickness and a width of 508 mm available under the trade designation “TEIJIN TETORON HB3” from DuPont Teijin Films Ltd., was loaded into the roll to roll vacuum chamber. The polyester web was sequentially plasma treated and then coated with an acrylate solution (Formulation 1), which was e-beam cured producing a first acrylate layer, during one pass through the vacuum chamber at a web speed of about 50 fpm (15 m/min). Plasma treatment proceeded as follows. The vacuum chamber pressure was reduced to 5×10⁻⁵ torr. Nitrogen gas at a flow rate of 65 sccm was introduced into the vacuum chamber through a SnO₂ source producing a pressure of 3.7×10⁻³ torr. The SnO₂ source was slightly reduced (non-stoichiometric). Plasma treatment was conducted at 1,000 watts power. Formation of the first acrylate layer proceeded as follows. Prior to coating the acrylate solution onto the polyester web, about 120 ml of the acrylate solution (Formulation 1) was degassed in a vacuum bell jar until reaching a pressure of 60 mTorr. The acrylate solution was loaded into a pressure cylinder with a 38 mm diameter and a 120-125 mL capacity. A lead-screw driven monomer pump was used to pump the solution from the cylinder through an ultrasonic atomizer at a rate of about 1.5 mL/min. After atomization, the acrylate solution was flash evaporated at a temperature of about 275° C., followed by condensing of the solution vapor onto the PET web. Condensation was facilitated by contacting the uncoated PET web surface to the circumference of a drum maintained at a temperature of ≦−17° C. The condensed solution was e-beam cured at a voltage of 8.5 KV and a current of 51 mA.

The polyester was run in the reverse direction and a first SnO₂ layer, a seed layer, was deposited on the web surface adjacent to the first acrylate layer. The same SnO₂ source used for plasma treatment was used for sputter coating of the first SnO₂ layer. Deposition of the first SnO₂ layer was conducted using an argon flow rate of 60 sccm, an oxygen flow rate of 10 sccm and a power of 2,000 watts at a line speed of 50 fpm (15 m/min). The polyester web was run in the forward direction and a first ZnO/Al₂O₃ (98:2 wt %/wt %) layer and a first Ag/Au metal alloy layer were sequentially deposited onto the surface of the web adjacent to the first acrylate layer at a line speed of 50 fpm (15 m/min). The ZnO/Al₂O₃ source, which was slightly reduced (non-stoichiometric), was sputter coated using an argon flow of 36 sccm and a power of 2,000 watts. Deposition of the Ag/Au metal alloy layer was conducted by introducing argon at a flow rate of 120 sccm into the vacuum chamber and DC magnetron through an 85/15 (wt/wt) Ag/Au source. The power level was 2,200 watts.

The web was run in the reverse direction and a second ZnO/Al₂O₃ layer was deposited using essentially the same materials and process conditions as those used to deposit the first ZnO/Al₂O₃ layer. While running the web in the forward direction, a second acrylate layer was deposited on the surface of the web adjacent to the second ZnO/Al₂O₃ layer producing Example 1. The materials and process conditions used to deposit the second acrylate layer were essentially the same as those used to produce the first acrylate layer, accept the monomer pump flow rate was 0.55 mL/min and the line speed was 65 fpm (19.8 m/min). The optical film of Example 1 was completed by the lamination of 3M OPTICALLY CLEAR ADHESIVE 8171 onto the support.

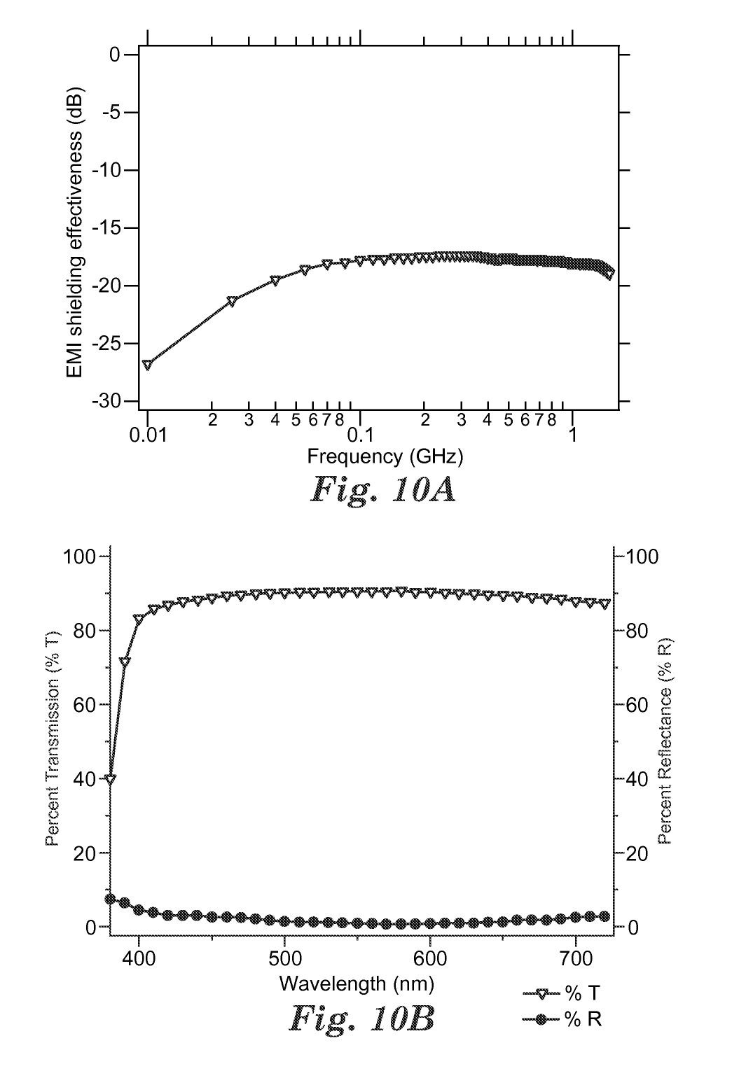

Surface resistivity data for the Example prior to and after reliability testing along with the reliability test results are shown in Table 2. Shielding effectiveness results are shown in FIG. 10A. Optical analysis results, both transmission and reflectance, are shown in FIG. 10B.

TABLE 2
Reliability Analysis and Electrical Analysis Test Results

| | | | | Surface | Surface |
|---|---|---|---|---|---|
| | | | Surface | Resistivity (ohms | Resistivity (ohms |
| | Chamber | Chamber | Resistivity | per square) after | per square) after |
| | Conditions | Conditions | (ohms per | Test Method 4: | Test Method 4: |
| Test Method | 65° C./90% RH | 85° C./85% RH | square) | 65° C./90% RH | 85° C./85% RH |
| Reliability | No Visual | No Visual | — | — | — |
| | Defects | Defects | | | |
| Electrical | — | — | 32.2 | 32.8 | 36.6 |

Patterning the Ag/Au Layer with Etching.

The sample from Example 1 was postcured by exposure to a H-bulb source having a dichroic reflector, with a UVC energy of 600 mJ/cm². The sample was than patterned by the deposition of a printable hydrocarbon wax mask that was printed with a line pattern. The sample was etched for one minute with a 10 wt % solution of FeCl₃ in water, followed by extensive rinsing with deionized water. After the etch process the mask was removed and the result was a set of conductive traces on non-conductive PET.

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows. All references cited in this disclosure are herein incorporated by reference in their entirety.

1. An optically transparent display filter comprising:
a transparent support that includes an optically clear adhesive; and
a multi-layer construction atop the support, the construction comprising:
a layer of metal oxide upon the support;
a polycrystalline seed layer comprising zinc oxide or bismuth oxide disposed upon the metal oxide layer;
a conductive metal or metal alloy layer disposed upon the polycrystalline seed layer; and
a barrier layer disposed upon the conductive metal or metal alloy layer,
wherein the multi-layer construction is atop the support on the side opposite the optically clear adhesive.

2. An optically transparent display filter according to claim 1, wherein the barrier layer comprises a crosslinked acrylic polymer.

3. An optically transparent display filter according to claim 1, further comprising a polymeric basecoat layer disposed between the support and the metal oxide layer.

4. An optically transparent display filter according to claim 1, wherein the electrically-conducting layer comprises an alloy of silver and at least one additional metal that has a lower oxidation potential than silver.

5. An optically transparent display filter according to claim 4, wherein the alloy contains about 85 weight percent silver and about 15 weight percent gold.

6. An optically transparent display filter according to claim 1, wherein the metal oxide layer comprises tin oxide.

7. (canceled)

8. An optically transparent display filter according to claim 1, wherein the polycrystalline seed layer comprises zinc oxide, aluminum-doped zinc oxide or a combination thereof.

9. An optically transparent display filter according to claim 1, wherein the optically clear adhesive comprises a crosslinked acrylic polymer.

10. An optically transparent display filter according to claim 1, further comprising at least one of an antireflection layer, a low friction coating layer, a polarizer, an antistatic layer, an abrasion resistant layer, an anti-fogging material layer, a magnetic of magneto-optic layer, an adhesion promoter, an anti-intrusion layer, a vibration-damping layer, a self-cleaning layer, a color-compensation layer, and an anti-corrosion layer.

11. An optically transparent display filter according to claim 1, further comprising a patterned second electrically-conducting metal or metal alloy layer adjacent to the first electrically-conducting layer.

12. An optically transparent display filter according to claim 11, further comprising a third patterned electrically conducting metal or metal alloy layer adjacent to the second electrically-conducting layer.

13. An optically transparent display filter according to claim 1, wherein the filter has a sheet resistance of less than 100 ohms/square.

14. An optically transparent display filter according to claim 1, wherein the filter provides EMI shielding of less than 30 dB when the frequency is in the range of from 1 GHz to 18 GHz.

15. An optically transparent display filter according to claim 1 further comprising a dye, pigment, or combination thereof that can absorb in one or more regions of the electromagnetic spectrum.

16. A display filter according to claim 1, further comprising a capacitive touch-sensitive support.

17. A display panel comprising at least one optical filter according to claim 1.

18. An electronic device comprising a display panel according to claim 17.

19. A touch sensitive electronic device comprising:
a transparent support that includes an optically clear adhesive; and
a multi-layer construction atop the support, the construction comprising:
a layer of metal oxide upon the support;
a polycrystalline seed layer comprising zinc oxide disposed upon the layer of metal oxide;
a patterned conductive metal or metal alloy layer disposed upon the polycrystalline seed layer;
a first barrier layer disposed upon the conductive metal or metal alloy layer;
a second layer of metal oxide disposed on top of the first barrier layer;
a second polycrystalline seed layer comprising zinc oxide disposed upon the second layer of metal oxide;
a second patterned metal or metal alloy layer disposed upon the second polycrystalline seed layer; and
a second barrier layer disposed upon the second conductive metal or metal alloy layer,
wherein the multi-layer construction is atop the support on the side opposite the optically clear adhesive.

20. A method of making a display filter comprising:
providing a transparent support that includes an optically clear adhesive;
coating a layer of metal oxide on top of the transparent support on the side opposite the adhesive;
vapor coating a polycrystalline seed layer comprising zinc oxide or bismuth oxide directly upon the metal oxide layer;
coating an electrically-conductive layer comprising a metal or metal alloy directly upon the polycrystalline seed layer; and
depositing a barrier layer in contact with the electrically-conductive layer.

21-22. (canceled)

23. A method of making a display filter comprising:
providing an optically transparent display filter comprising:
a transparent support that includes an optically clear adhesive; and
a multi-layer construction atop the support on the side opposite the adhesive, the construction comprising:
a layer of metal oxide upon the support;
a polycrystalline seed layer comprising zinc oxide disposed upon the metal oxide layer;
a conductive metal or metal alloy layer disposed upon the polycrystalline seed layer; and
a barrier layer disposed upon the conductive metal or metal alloy layer; and patterning the electrically-conducting metal or metal alloy layer.
